(19) United States
(12) Patent Application Publication
(10) Pub. No.: US 2016/0284281 A1
(43) Pub. Date: Sep. 29, 2016

(54) DISPLAY APPARATUS AND CONTROL DEVICE

(71) Applicant: SHARP KABUSHIKI KAISHA, Osaka-shi, Osaka (JP)

(72) Inventors: Tatsuhiko SUYAMA, Osaka-shi (JP); Kentaroh UEMURA, Osaka-shi (JP); Norio OHMURA, Osaka-shi (JP)

(21) Appl. No.: 15/033,530

(22) PCT Filed: Oct. 31, 2014
(86) PCT No.: PCT/JP2014/079077

§ 371 Date: Apr. 29, 2016

(30) Foreign Application Priority Data
Nov. 1, 2013 (JP) 2013-227936

(51) Int. Cl. G09G 3/34; H01L 27/12; G09G 3/36

(52) U.S. Cl. CPC G09G 3/3406; G09G 3/3648; G09G 3/3677; H01L 27/1225; H01L 27/124; G09G 2320/0247; G09G 2330/023; G09G 2320/0653; G09G 2320/041; G09G 2300/0809

(57) ABSTRACT

It is an object of the invention to inhibit deterioration in display quality and reduce electric power consumption in a display apparatus. A display apparatus (1) includes a display panel (2) having a display provided with a plurality of pixels, a backlight unit (3) configured to emit light to the display, a panel controller (4) configured to control writing operation of supplying each of the pixels with a signal to display an image in the display and a suspension period provided between the writing operation and different writing operation, and a backlight unit controller (5) configured to control light quantity of the backlight unit (3) in synchronization with writing operation performed before or after the suspension period.

### TECHNICAL FIELD

The present disclosure relates to a technique of controlling a display panel and a backlight unit included in a display apparatus.

### BACKGROUND ART

Recent trends in display apparatuses include reduction in thickness, weight, and electric power consumption. JP 2004-078124 A proposes a technique for reducing electric power consumed by a display apparatus. Specifically, JP 2004-078124 A discloses a driving method including provision of a non-refresh period (suspension period) with all scanning signal lines in a non-scanning state. The non-refresh period is provided between scanning periods (refresh periods) for scanning of a screen of an active matrix panel. JP 2004-078124 A also discloses stopping a drive circuit configured to drive the active matrix panel and stopping a clock signal generation circuit having large electric power consumption during the non-refresh period.

### DISCLOSURE OF THE INVENTION

According to the driving method including provision of the suspension period as disclosed in JP 2004-078124 A, as the number of frames during the suspension period (the number of suspension frames) increases, electric power consumption decreases whereas time from rewriting the screen to subsequent rewriting becomes longer. In other words, increase in the number of suspension frames prolongs time from refreshing each pixel on the screen to subsequent refreshing. If this time is longer, pixel luminance variation due to refreshing becomes more visually recognizable. This may cause deterioration in display quality of a displayed image due to flickering or a persistent image.

The present application discloses a display apparatus configured to inhibit deterioration in display quality and reduce electric power consumption.

A display apparatus according to the present disclosure includes a display panel including a display provided with a plurality of pixels, a backlight unit configured to emit light to the display, a panel controller configured to control writing operation of supplying each of the pixels with a signal to display an image in the display, and a suspension period provided between the writing operation and writing operation performed before or after the writing operation, and a backlight unit controller configured to change light quantity of the backlight unit in synchronization with the writing operation.

The display apparatus according to the present disclosure is configured to inhibit deterioration in display quality and reduce electric power consumption.

### BRIEF DESCRIPTION OF DRAWINGS

FIG. 1 is a block diagram depicting an outline configuration of a display apparatus according to a first embodiment.

FIG. 2 is a sectional view depicting exemplary configurations of a display panel and a backlight unit.

FIG. 3 is a diagram depicting a more detailed exemplary configuration of the display apparatus.

FIG. 4 is a schematic sectional view of a pixel.

FIG. 5 is an explanatory graph indicating exemplary operation of a display apparatus 1.

FIG. 6 is a view indicating exemplary timings of writing operation and change in light quantity of a backlight unit 3.

FIG. 7 is an explanatory view exemplifying setting of various values for control of light quantity of the backlight unit.

FIG. 8 is an explanatory graph indicating operation of the display apparatus 1 according to a modification example.

FIG. 9 is an explanatory view exemplifying setting of various values for control of light quantity of the backlight unit according to the modification example.

FIG. 10 is a diagram depicting an exemplary configuration of a display apparatus according to a second embodiment.

FIG. 11 indicates a waveform W9 exemplifying change in light quantity of a backlight unit 3.

FIG. 12 is a diagram depicting an exemplary configuration of a display apparatus according to a third embodiment.

FIG. 13 is a graph indicating exemplary operation of a display apparatus 1 according to the third embodiment.

FIG. 14 is a diagram depicting an exemplary configuration of a display apparatus 1 according to a fourth embodiment.

FIG. 15 is a graph indicating exemplary operation of the display apparatus 1 according to the fourth embodiment.

### DESCRIPTION OF EMBODIMENTS

A display apparatus according to an embodiment of the present invention includes a display panel including a display provided with a plurality of pixels, a backlight unit configured to emit light to the display, a panel controller configured to control writing operation of supplying each of the pixels with a signal to display an image in the display, and a suspension period provided between the writing operation and writing operation performed before or after the writing operation, and a backlight unit controller configured to control light quantity of the backlight unit in synchronization with the writing operation.

In the above configuration, the panel controller controls the suspension period and the writing operation of supplying each of the pixels with the signal to display the image in the display. Provision of the suspension period leads to reduction in electric power consumption. The panel controller also controls the light quantity of the backlight unit in synchronization with the writing operation. The light quantity of the backlight unit thus moderates luminance variation due to the writing operation. This inhibits deterioration in display quality such as a persistent image or flickering. The display apparatus thus achieves inhibition of deterioration in display quality and reduction in electric power consumption.

In the above configuration according to an aspect, the backlight unit controller determines whether or not to change the light quantity of the backlight unit in synchronization with the writing operation in accordance with a result of comparison between the image displayed by the writing operation and an image displayed by writing operation performed before the writing operation.

Whether or not the light quantity of the backlight unit needs to be changed upon the writing operation is thus determined in accordance with whether or not the image is changed from the previous writing operation. This enables appropriate determination of whether or not luminance variation needs to be moderated by the change in light quantity of the backlight unit.

In the above configuration according to an aspect, the backlight unit controller determines whether or not to change the light quantity of the backlight unit in synchronization with the writing operation in accordance with length of the suspension period.

Whether or not the light quantity of the backlight unit needs to be changed in synchronization with the writing operation is thus determined in accordance with the length of the suspension period. This enables appropriate determination of whether or not the light quantity of the backlight unit needs to be changed for moderating luminance variation due the writing operation.

In the above configuration according to an aspect, the backlight unit controller controls to change the light quantity at a plurality of steps in a certain period. This reduces an influence of rapid change in light quantity of the backlight unit on display quality.

In the above configuration according to an aspect, the display apparatus further includes a temperature sensor configured to detect temperature, and the backlight unit controller modulates a degree of change in light quantity of the backlight unit in accordance with the temperature detected by the temperature sensor. An amount of luminance correction by means of the light quantity of the backlight unit is thus modulated in accordance with the temperature. This achieves further improvement in display quality.

In the above configuration according to an aspect, the panel controller sequentially selects lines of the pixels disposed in a matrix form in the display by supplying scanning lines connected to the lines with scanning signals and supplies the pixels on the selected lines with data signals to display the image in the writing operation, and stops writing data signals partially or entirely in the display during the suspension period. Such control of the writing operation and the suspension period leads to reduction in electric power consumption.

The display panel in the above configuration optionally includes an active matrix substrate. According to an aspect, the active matrix substrate includes scanning lines and data lines disposed to cross the scanning lines, a pixel electrode provided at each of the pixels defined by the scanning lines and the data lines, and a thin film transistor. According to an aspect, the thin film transistor has a semiconductor layer containing an oxide semiconductor disposed to face an electrode connected to a corresponding one of the scanning lines, a first electrode connected to the pixel electrode, and a second electrode connected to a corresponding one of the data lines, and the first electrode and the second electrode are provided apart from each other on the semiconductor layer.

The thin film transistor is provided as a switching element configured to switch on and off connection between the data line and the pixel electrode in accordance with a signal supplied to the scanning line. When the semiconductor layer of the thin film transistor contains the oxide semiconductor, the thin film transistor serves as a switching element having an excellent on-property.

According to an aspect, the display panel includes an active matrix substrate and a counter substrate provided to face the active matrix substrate with a liquid crystal layer being interposed therebetween.

According to another exemplary embodiment of the present invention, a control device of a display apparatus includes a display panel having a display provided with a plurality of pixels, and a backlight unit configured to emit light to the display. The control device includes a panel controller configured to control writing operation of supplying each of the pixels with a signal to display an image in the display, and a suspension period provided between the writing operation and writing operation performed before or after the writing operation, and a backlight unit controller configured to change light quantity of the backlight unit in synchronization with the writing operation.

Embodiments of the present invention will be described in detail below with reference to the drawings. Identical or corresponding portions in the drawings will be denoted by identical reference signs and will not be described repeatedly. For clearer description, the drawings to be referred to hereinafter may depict simplified or schematic configurations or may not depict some of constructional elements. The constructional elements in each of the drawings may not necessarily be depicted in actual dimensional ratios.

### First Embodiment

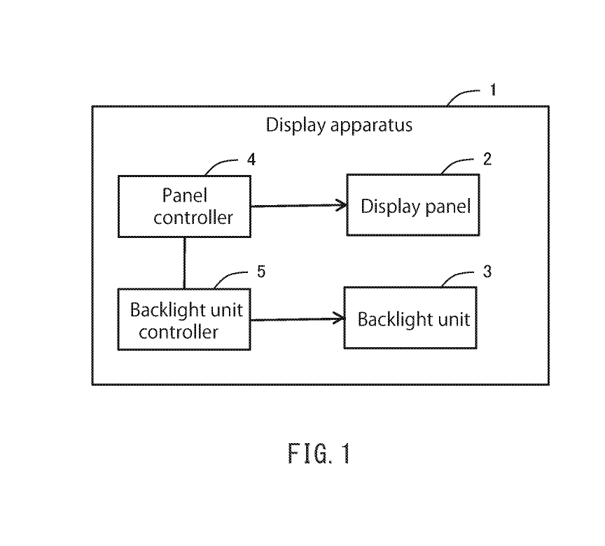

(Exemplary configuration of display apparatus) FIG. 1 is a functional block diagram depicting a configuration of a display apparatus according to the first embodiment. FIG. 1 exemplarily depicts a display apparatus 1 including a display panel 2 having a display provided with a plurality of pixels, a backlight unit 3 configured to emit light to the display, a panel controller 4, and a backlight unit controller 5. The panel controller 4 controls driving the display panel 2 in accordance with an image signal received from the outside. The panel controller 4 according to the present embodiment controls at least writing operation of supplying each pixel with a signal to display an image in the display and a suspension period provided between the writing operation and writing operation performed before or after the writing operation. The backlight unit controller 5 controls light quantity of the backlight unit 3 in synchronization with writing operation. In other words, light quantity of the backlight unit 3 is controlled at a timing of writing operation. According to an aspect, the backlight unit controller 5 is configured to start changing light quantity of the backlight unit 3 at the start of writing operation controlled by the panel controller 4. The backlight unit controller 5 controls light quantity of the backlight unit 3 at a timing of writing operation controlled by the panel controller 4 to moderate pixel luminance variation due to the writing operation by means of light from the backlight unit 3.

(Exemplary Configurations of Display Panel and Backlight Unit)

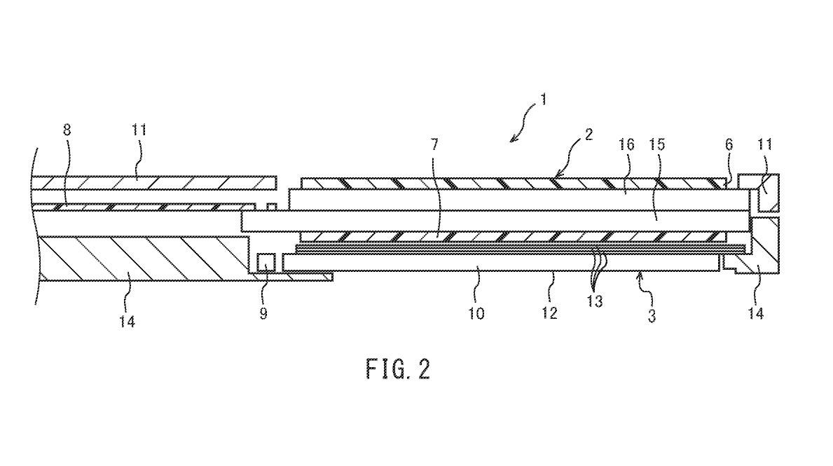

FIG. 2 is a sectional view depicting exemplary configurations of the display panel 2 and the backlight unit 3. FIG. 2 exemplarily depicts the display apparatus 1 configured as a liquid crystal display apparatus. The display apparatus 1 includes the display panel 2 configured as a liquid crystal panel and disposed to have an upper surface in FIG. 2 to be viewed (display surface), and the backlight unit 3 facing a non-display surface (lower surface in FIG. 1) of the display panel 2 and configured to emit light illuminating the display panel 2.

The display panel 2 includes an active matrix substrate 15 and a counter substrate 16. The active matrix substrate 15 and the counter substrate 16 face each other with a liquid crystal layer (not depicted) being interposed therebetween. In other words, the liquid crystal layer is sandwiched between the counter substrate 16 and the active matrix substrate 15.

The counter substrate 16 and the active matrix substrate 15 have outer surfaces provided with polarizing plates 6 and 7, respectively. The polarizing plates 6 and 7 are stuck to the counter substrate 16 and the active matrix substrate 15, respectively, to cover at least an effective display region of the display provided in the display panel 2. According to an aspect, the counter substrate 16 and the active matrix substrate 15 are made of a flat transparent glass material or transparent synthetic resin such as acrylic resin According to an aspect, the polarizing plates 6 and 7 are each configured by as a resin film made of triacetylcellulose (TAC), polyvinyl alcohol (PVA), or the like. A λ/4 retardation film (quarter wave plate) is occasionally provided between each of the polarizing plates 6 and 7 and the liquid crystal layer.

The active matrix substrate 15 and the liquid crystal layer are provided therebetween with pixel electrodes, thin film transistors (TFTs), and the like so as to be associated with the plurality of pixels provided in the display of the display panel 2 (to be described in detail later). The counter substrate 16 and the liquid crystal layer are provided therebetween with color filters, counter electrodes, and the like (not depicted).

FIG. 2 exemplarily depicts the display panel 2 including the active matrix substrate 15 connected with a flexible printed circuit (FPC) 8. The active matrix substrate 15 is provided with wiring that is configured to supply each pixel with a signal and is led to the FPC 8. According to an aspect, the wiring led to the FPC 8 is connected with an IC chip or a circuit partially configuring the panel controller 4 or the backlight unit controller 5. The liquid crystal layer is configured to operate in a pixel unit in accordance with control by the panel controller 4. The display is thus configured to display a desired image.

The display panel 2 is optionally configured in terms of its liquid crystal mode and its pixel structure. The display panel 2 is optionally configured also in terms of its drive mode. In other words, an appropriate liquid crystal panel configured to display information is applicable as the display panel 2. Accordingly, a detailed structure of the display panel 2 will be neither depicted in FIG. 2 nor described herein.

The backlight unit 3 includes a light-emitting diode 9 serving as a light source, and a light-guiding plate 10 facing the light-emitting diode 9. The light-emitting diode 9 and the light-guiding plate 10 in the backlight unit 3 are sandwiched by a bezel 14 having an L sectional shape. The display of the display panel 2 is disposed above the light-guiding plate 10. The counter substrate 16 is mounted thereon with a case 11. The backlight unit 3 is thus assembled to the display panel 2. In this manner, there is provided a transmissive liquid crystal display apparatus allowing illumination light emitted from the backlight unit 3 to be incident on the display panel 2.

The light-guiding plate 10 receives light from the light-emitting diode 9. According to an aspect, the light-guiding plate 10 is made of synthetic resin such as transparent acrylic resin. The light-guiding plate 10 is provided with a reflective sheet 12 on a surface not facing the display panel 2 (on an opposite surface). The light-guiding plate 10 is provided, on a surface facing the display panel 2 (on a light-emitting surface), with optical sheets 13 such as a lens sheet and a diffusion sheet. Light emitted from the light-emitting diode 9 and guided in a predetermined light guiding direction (from the left to the right in FIG. 1) inside the light-guiding plate 10 is converted to the illumination light, which has uniform luminance and is planar, and is applied to the display panel 2.

The above description refers to a configuration including an edge lighting backlight device provided with the light-guiding plate 10. The present embodiment is, however, not limited to this configuration, and alternatively adopts a direct backlight device. The present embodiment still alternatively adopts a backlight device having a light source such as a cold cathode fluorescent tube or a hot cathode fluorescent tube, in place of the light-emitting diode.

(Exemplary Configurations of Panel Controller and Display)

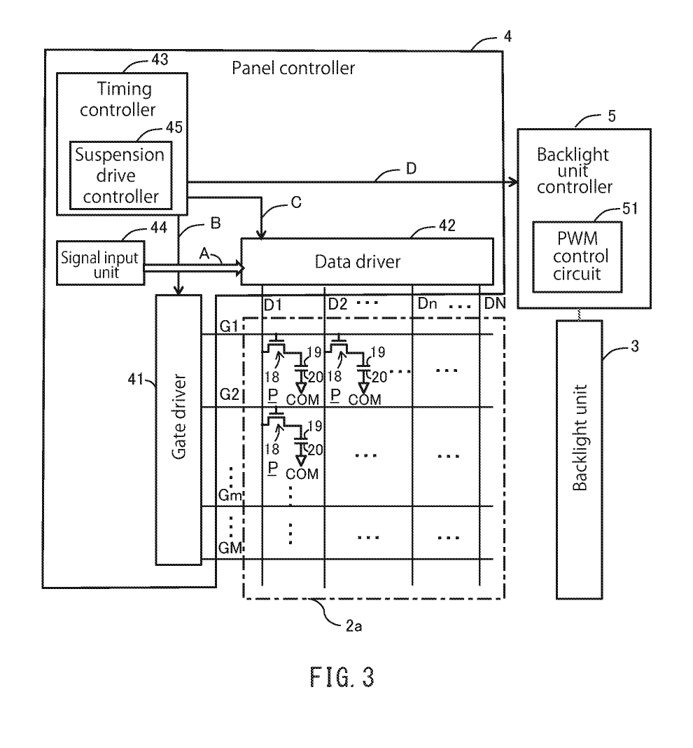

FIG. 3 is a diagram depicting a more detailed exemplary configuration of the display apparatus 1. FIG. 3 exemplarily depicts the panel controller 4 including a gate driver 41, a data driver 42, a timing controller 43, and a signal input unit 44. The timing controller 43 includes a suspension drive controller 45. The backlight unit controller 5 includes a PWM control circuit 51.

The signal input unit 44 supplies the data driver 42 with an image signal according to image data received from the outside (arrow A). The timing controller 43 supplies each of the data driver 42 and the gate driver 41 with a control signal (arrows B and C) to control a timing of supplying a signal according to the image signal to each pixel from each of the data driver 42 and the gate driver 41. When the data driver 42 and the gate driver 41 drive, information according to the image signal is displayed in a display 2a of the display panel 2. Operation of supplying each pixel with a signal to display an image in the display 2a, in other words, writing operation, is performed in this manner.

The suspension drive controller 45 in the timing controller 43 controls writing operation, and whether or not to provide a suspension period between the writing operation and previous or subsequent writing operation or length of the suspension period. The gate driver 41 and the data driver 42 according to the present embodiment are controlled to suspend operation during a suspension period. In other words, operation of changing a voltage applied to each pixel (operation of supplying each pixel with a signal) is suspended during a suspension period. This leads to reduction in electric power consumption. The suspension drive controller 45 synchronizes a signal commanding drive or suspension with the control signal and transmits the synchronized signal to each of the gate driver 41 and the data driver 42 so as to control a timing of starting or ending a suspension period or length of the suspension period.

The active matrix substrate 15 is provided with M (M is a natural number) gate lines (scanning lines) G1, G2, . . . , Gm, . . . , and GM (hereinafter, collectively denoted by “G”), and N (N is a natural number) data lines (source lines) D1, D2, . . . , Dn, . . . , and DN (hereinafter, collectively denoted by “D”). The data lines D are disposed to cross the gate lines G. The gate lines G are connected to the gate driver 41 whereas the data lines D are connected to the data driver 42.

The data lines D and the gate lines G have intersection points provided with pixels P, respectively. Each of the pixels P includes a thin film transistor (TFT) 18 and a pixel electrode 19 connected to the TFT 18. The TFT 18 has a gate connected with a corresponding one of the gate lines G, a source connected with a corresponding one of the data lines D, and a drain connected with the pixel electrode 19. Each of the pixels P is also provided with a counter electrode 20 that faces the pixel electrode 19 with the liquid crystal layer provided in the display panel 2 being interposed therebetween. In this manner, the active matrix substrate 15 has regions divided in a matrix form by the data lines D and the gate lines G, and these regions are provided with the plurality of pixels P, respectively. The display 2a corresponds to the regions provided with the pixels P in the display panel 2.

Upon writing operation, the gate driver 41 sequentially supplies the gate lines G connected to the pixels on respective lines in the matrix form with scanning signals in accordance with a signal from the timing controller 43 to sequentially select the respective lines. The data driver 42 supplies the pixels on the selected lines with data signals according to an image signal from the signal input unit 44. The suspension drive controller 45 outputs an AMP_Enable signal exemplifying a control signal prescribing an operation state of each analog amplifier (not depicted) configuring the data driver 42. Each of the analog amplifiers operates if the AMP_Enable control signal has an H value, and is suspended if the AMP_Enable control signal has an L value. The data lines D thus have unvaried potential during a suspension period. The gate lines G are in a non-scanning state during a suspension period. Accordingly, writing operation to each pixel is not performed during a suspension period.

(Exemplary Configuration of Backlight Unit Controller)

FIG. 3 exemplarily depicts the backlight unit controller 5 including the PWM control circuit 51. The PWM control circuit 51 receives a signal indicating a timing of writing operation from the timing controller (arrow D). The PWM control circuit 51 changes light quantity of the backlight unit at the timing indicated by this signal.

In an exemplary case, the PWM control circuit 51 pulse-width-modulation (PWM) controls current flowing to the backlight unit 3 so as to allow light quantity of the backlight unit to be controlled. The PWM control circuit 51 changes pulse width of the current flowing to the backlight unit 3 in accordance with a duty ratio preliminarily stored in a registry so as to allow light quantity of the backlight unit to be changed. According to an aspect, an amount of change in light quantity of the backlight unit 3 is preliminarily stored in this manner.

Control of light quantity of the backlight unit 3 is not limited to PWM control. Alternatively, a current value of the backlight unit 3 is changed.

The PWM control circuit 51 controls light quantity of the backlight unit 3 in synchronization with operation of writing an image in the display panel 2. According to an aspect, light quantity starts changing simultaneously at the start of writing operation, after elapse of predetermined time from the start of the writing operation to the end of writing in a single frame, after elapse of predetermined time from the end of the writing operation to the start of subsequent writing operation, or the like. Alternatively, light quantity of the backlight unit 3 is changed stepwise within a certain period from the start of the writing operation. Assuming that a single frame writing period is 16.7 ms, the start of the single frame writing period is “simultaneously at the start of writing operation” and the middle of the single frame writing period is “8.35 ms after the start of the writing operation”.

Data indicating the start timing of change in light quantity or the stepwise change is stored in the registry or the like. The PWM control circuit 51 is configured to control light quantity of the backlight unit in accordance with the data stored in the registry.

According to an aspect, the amount of change in light quantity of the backlight unit and the timing of the change are set in accordance with an amount of luminance variation due to voltage application to each pixel, for example. In an exemplary case, luminance variation in response to voltage application to each pixel is relevant to a liquid crystal response property in response to voltage application. The amount of change in light quantity of the backlight unit is thus set in accordance with the liquid crystal response property.

The backlight unit controller 5 is alternatively configured to dynamically determine the amount of change in light quantity of the backlight unit and/or the timing of the change in accordance with drive status. The amount of change in light quantity and/or the timing of the change is determined in accordance with a tone value of a writing target pixel, change in image from previous writing operation, length of a suspension period, temperature, or the like. The backlight unit controller 5 updates, in accordance with drive status, set values indicating the amount of change in light quantity and/or the timing of the change and stored in the registry or the like, so as to dynamically control the amount of change in light quantity and/or the timing of the change. Light quantity of the backlight unit 3 is thus changed more appropriately in accordance with drive status.

(Exemplary Configuration of Pixel)

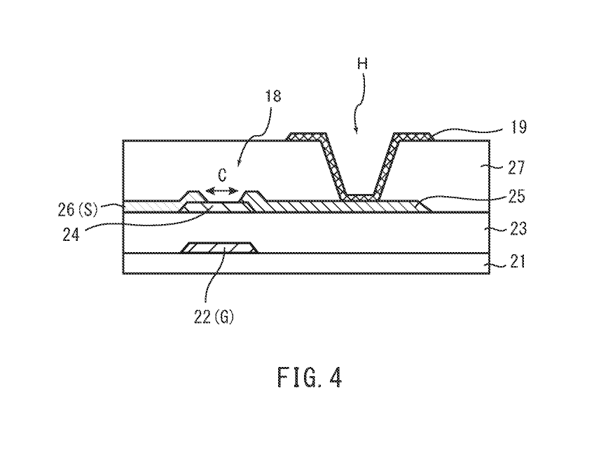

FIG. 4 is a schematic sectional view of the pixel P. FIG. 4 exemplarily depicts the active matrix substrate 15 including a glass substrate 21 provided thereon with a gate electrode 22. Such provision of the gate electrode 22 allows the gate line G and the gate of the TFT 18 to be provided integrally with each other. The gate electrode 22 is provided thereon with a gate insulating film 23. A semiconductor layer 24 is disposed to face the gate electrode 22 with the gate insulating film 23 being interposed therebetween. The semiconductor layer 24 is provided thereon with a source electrode 26 and a drain electrode 25 that are spaced apart from each other. The semiconductor layer 24 is also provided thereon with a channel region that is sandwiched between the source electrode 26 and the drain electrode 25. The source electrode 26 is provided integrally with the gate line G and is thus connected to the gate line G. The drain electrode 25 is connected to the pixel electrode 19. The gate insulating film 23 is provided thereon with a protective layer 27 covering the semiconductor layer 24, the source electrode 26, and the drain electrode 25. The protective layer 27 is configured by an insulating film made of SiO₂ or the like. The protective layer 27 is provided thereon with the pixel electrode 19. The pixel electrode 19 is connected with the drain electrode 25 via a contact hole H provided in the protective layer 27.

The semiconductor layer 24 according to the present embodiment includes an oxide semiconductor. The oxide semiconductor is exemplified by InGaZnOx mainly containing indium (In), gallium (Ga), zinc (Zn), and oxygen (O). The InGaZnOx as an In—Ga—Zn—O semiconductor is ternary oxide of In, Ga, and Zn and is not particularly limited in terms of ratios (composition ratios) of In, Ga, and Zn. The ratios In:Ga:Zn are exemplified by 2:2:1, 1:1:1, 1:1:2, and the like. The semiconductor layer 24 according to the present embodiment is made of the In—Ga—Zn—O semiconductor containing In, Ga, and Zn in the ratios of 1:1:2 or the like. The TFT 18 having the semiconductor layer 24 containing the In—Ga—Zn—O semiconductor has mobility at least about 20 times that of a TFT containing a-Si and leakage current less than about one hundredth that of the TFT. Such an oxide semiconductor is appropriately applied to a TFT configured to drive a pixel. The display apparatus 1 including the TFT 18 provided with the semiconductor layer 24 containing the In—Ga—Zn—O semiconductor achieves significant reduction in electric power consumption.

The In—Ga—Zn—O semiconductor is amorphous or contains a crystalline substance to have crystallinity. Such an In—Ga—Zn—O semiconductor containing a crystalline substance preferably has a c axis oriented substantially perpendicular to a layer surface. A crystalline structure of such an In—Ga—Zn—O semiconductor is disclosed in JP 2012-134475 A and the like. The entirety of the disclosure in JP 2012-134475 A is incorporated herein for a reference purpose.

Alternatively, the semiconductor layer 24 includes an oxide semiconductor other than the In—Ga—Zn—O semiconductor. Specifically, the semiconductor layer 24 includes a Zn—O semiconductor (ZnO), an In—Zn—O semiconductor (IZO (registered trademark)), a Zn—Ti (titanium) —O semiconductor (ZTO), a Cd (cadmium) —Ge (germanium) —O semiconductor, a Cd—Pb (lead) —O semiconductor, a CdO (cadmium oxide) —Mg (magnesium) —Zn—O semiconductor, an In—Sn (tin) —Zn—O semiconductor (e.g. In₂O₃—SnO₂—ZnO), an In—Ga (gallium) —Sn—O semiconductor, or the like.

(Exemplary Drive of Display Apparatus)

When the display apparatus 1 is driven, the timing controller 43 depicted in FIG. 3 receives a horizontal synchronization signal (HSYNC) and a vertical synchronization signal (VSYNC) as input picture synchronization signals. The timing controller 43 generates, in accordance with these input picture synchronization signals, a horizontal synchronization control signal (e.g. OCR) and a vertical synchronization control signal (e.g. GSP) as reference picture synchronization signals for synchronous operation of respective circuits. The timing controller 43 transmits the generated signals to each of the gate driver 41 and the data driver 42 (arrows B and C in FIG. 3).

The horizontal synchronization control signal is used in the data driver 42 as an output timing signal for control of a timing of transmitting an image signal received from the outside to each of the data lines D. The horizontal synchronization control signal is also used in the gate driver 41 as a timing signal for control of a timing of transmitting a scanning signal to each of the gate lines G. The vertical synchronization control signal is used in the gate driver 41 as a timing signal for control of a start timing of scanning each of the gate lines G.

Unless otherwise specified, in the present embodiment, a “single vertical period (single frame period)” is prescribed by the vertical synchronization control signal, and a “single horizontal period” is prescribed by the horizontal synchronization control signal.

The suspension drive controller 45 transmits, to the data driver 42, an AMP_Enable signal in synchronization with the vertical synchronization control signal and the horizontal synchronization control signal thus generated. The suspension drive controller 45 outputs the AMP_Enable signal having the H value to operate the analog amplifiers in the data driver 42 during a period of writing operation (hereinafter, referred to as a drive period). The suspension drive controller 45 outputs the AMP_Enable having the L value to suspend the analog amplifiers during a suspension period. The suspension drive controller 45 is optionally configured to set an appropriate number of frames as drive frames and set an appropriate number of frames as suspension frames, or configured to control these frames in an irregular manner.

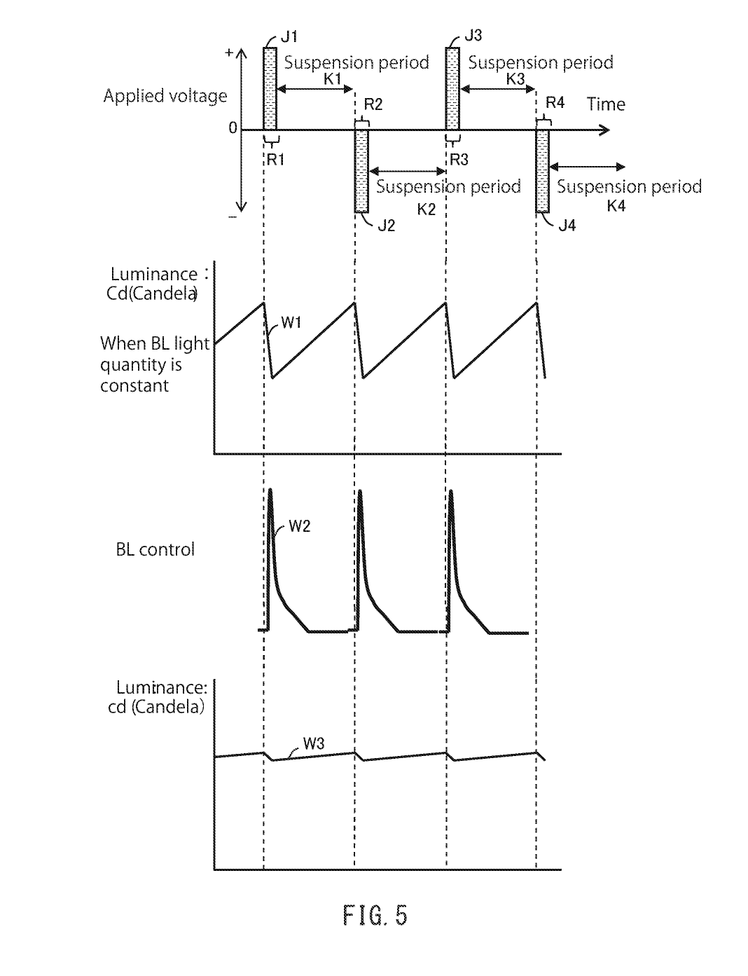

FIG. 5 is an explanatory graph indicating exemplary operation of the display apparatus 1. The uppermost section in FIG. 5 indicates temporal change in signal voltage written to the data lines D. FIG. 5 exemplarily indicates a case where drive periods R1, R2, R3, and RA and suspension periods K1, K2, K3, and K4 are provided alternately. A drive period and a subsequent suspension period are collectively referred to as a suspension drive period. Signal voltages J1, J2, J3, and J4 are applied to the data lines D during the drive periods R1, R2, R3, and R4, respectively. The suspension periods are longer than the drive periods in this exemplary case. According to FIG. 5, the signal voltages written to the data lines D during the drive periods have polarities inverted in each of the suspension drive periods.

The second section from the top in FIG. 5 indicates a waveform W1 exemplifying pixel luminance variation in a case of driving with the signal voltages indicated in the uppermost section and keeping light quantity of the backlight unit 3 unchanged. In the case of the second section from the top in FIG. 5, luminance rapidly decreases immediately after the start of signal voltage application during a drive period, then recovers moderately, and reaches a level corresponding to the signal voltage in a suspension period subsequent to the drive period. This exemplifies a case where a luminance property significantly changes upon writing operation during a drive period. This luminance variation is regarded as a phenomenon caused due to the fact that an oriented manner of liquid crystal molecules fails to follow inversion of the signal voltage polarities. If images change at high speed as in a case where a motion picture is displayed, a viewer hardly recognizes luminance variation. If an image remains unchanged during a suspension drive period, a viewer is likely to recognize luminance variation as flickering. This will lead to deterioration in display quality.

The third section from the top in FIG. 5 indicates a waveform W2 exemplifying change in light quantity of the backlight unit 3 controlled by the backlight unit controller 5. In this exemplary case, light quantity of the backlight unit 3 rapidly increases at the start of a drive period, then decreases moderately, and recovers to an original level during a suspension period subsequent to the drive period. In this manner, light quantity of the backlight unit 3 is changed to counteract pixel luminance variation due to signal voltage application, so as to moderate the luminance variation due to the signal voltage application during a drive period.

The fourth section (at the bottom) in FIG. 5 indicates a waveform W3 of luminance variation in a case where light quantity of the backlight unit 3 is changed as indicated in the third section from the top in FIG. 5. Luminance variation due to signal voltage application during a drive period is moderated in this exemplary case. In other words, backlight luminance variation counteracts luminance variation due to signal voltage application. In such a display apparatus having luminance that tends to decrease upon writing operation, luminance variation is inhibited by increasing power of the backlight unit 3 at a timing of the writing operation. The second and fourth sections from the top in FIG. 5 each have an ordinate axis indicating luminance and a transverse axis indicating time. Luminance is indicated by the unit of candela (cd) or the like.

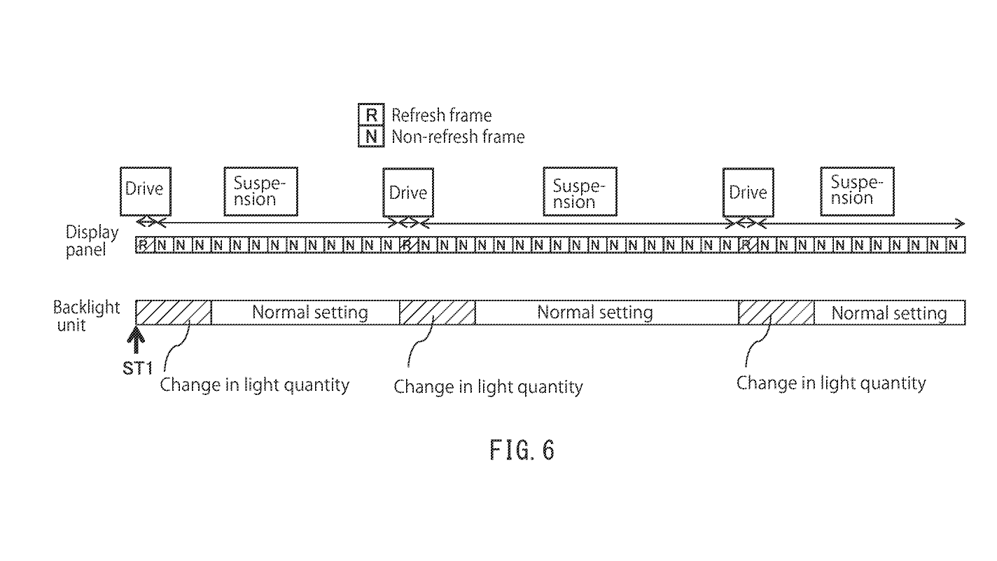

FIG. 6 is a view indicating exemplary timings of writing operation and change in light quantity of the backlight unit 3. FIG. 6 exemplarily indicates a case where the display panel 2 has drive periods each configured by a drive frame (refresh frame) and suspension periods each configured by a plurality of suspension frames (non-refresh frames), and the drive periods and the suspension periods are provided alternately. The backlight unit controller 5 starts controlling light quantity of the backlight unit 3 in synchronization with the start of a drive frame. The backlight unit controller 5 stepwise changes light quantity during three suspension frames subsequent to the drive frame, and ends the change in light quantity in synchronization with the end of the third suspension frame. Writing operation (refreshing) performed once alternatively lasts for a plurality of drive frames.

By performing writing operation and changing light quantity of the backlight unit in synchronization with each other during a drive period, the backlight unit inhibits luminance variation due to the writing operation at a more appropriate timing. When light quantity is set to change gradually during a plurality of frames in addition to a frame for image writing, rapid change of light of the backlight unit 3 is inhibited from influencing display quality.

The backlight unit controller 5 is configured to receive, from the timing controller 43, a vertical synchronization control signal, a horizontal synchronization control signal, and an AMP_Enable signal as signals indicating a timing of writing operation. The backlight unit controller 5 is configured to change light quantity of the backlight unit 3 at a timing of the start of a drive frame or the end of a suspension frame, or at a timing of writing operation to the lines in a frame.

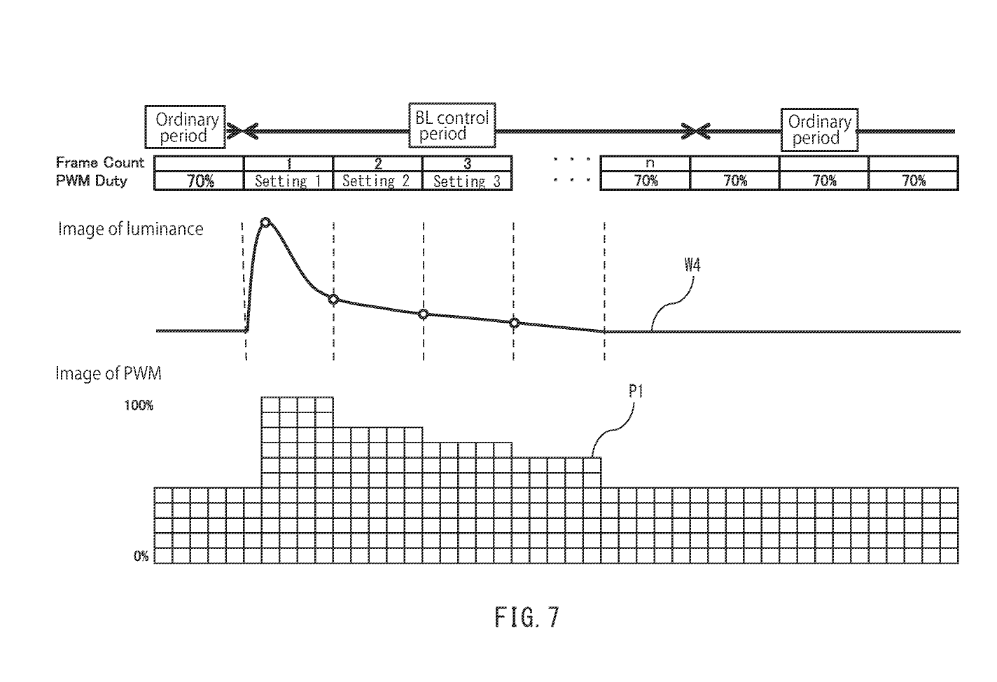

FIG. 7 is an explanatory view exemplifying setting of various values for control of light quantity of the backlight unit. FIG. 7 indicates exemplary setting of PWM duty ratios in a case where light quantity of the backlight unit is changed stepwise during a plurality of frame periods. FIG. 7 exemplifies setting of a duty ratio during an ordinary period (e.g. 70%) and duty ratios of n frames during a backlight control period (BL control period) (setting 1, setting 2, setting 3, . . . , and setting n). The duty ratios during the BL control period are set for the respective frames. The duty ratios of the frames during the BL control period are set with magnifications to a value for the ordinary period, for example. In an exemplary case, values from 1.04 to 1.14 are set for the respective frames during the BL control period. If an n-th frame in the BL control period has a set value of 1.08, the duty ratio of the n-th frame is 75.6%, which is obtained by multiplying the duty ratio during the ordinary period (70%) by 1.08.

FIG. 7 includes a waveform W4 indicating an image of backlight luminance variation, and blocks P1 indicating an image of pulse width in the PWM. FIG. 7 exemplifies a case where the duty ratios are set such that light quantity of the backlight unit rapidly increases and reaches a peak in the first frame during the BL control period, decreases in the second and subsequent frames, and recovers to an original level in the n-th frame. The pulse width in the PWM is set to be the largest in the first frame, decrease stepwise in the second to n-th frames, and be equal to the value for the ordinary period (70%) in the n-th frame.

Light quantity has a set value for each of the frames in the exemplary case of FIG. 7. There is, however, not always need to control light quantity in each of the frames. According to an aspect, a start position of change in light quantity is set for each of the lines. The start position of change is alternatively set in the second or a subsequent frame during the BL control period. According to an aspect, the set values are stored in a register configured to be referred to by the backlight unit controller 5.

(Drive According to Modification Example)

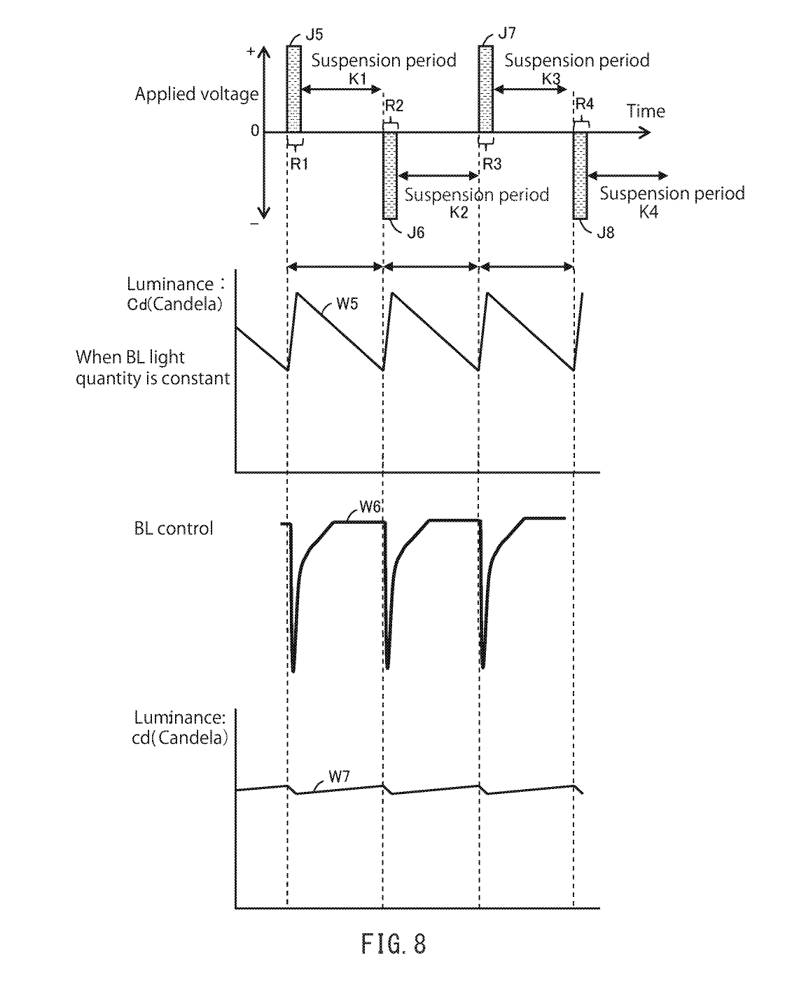

FIG. 8 is an explanatory graph indicating operation of the display apparatus 1 according to a modification example. The uppermost section in FIG. 8 indicates temporal change in signal voltage written to the data lines D. FIG. 8 exemplarily indicates a case where the drive periods R1, R2, R3, and RA and the suspension periods K1, K2, K3, and K4 are provided alternately. Signal voltages J5, J6, J7, and J8 are applied to the data lines D during the drive periods R1, R2, and R3, respectively.

The second section from the top in FIG. 8 indicates a waveform W5 exemplifying pixel luminance variation in a case of driving with the signal voltages indicated in the uppermost section and keeping light quantity of the backlight unit 3 unchanged. In this exemplary case, luminance rapidly increases immediately after wiring a signal voltage to each pixel during a drive period, then decreases moderately, and reaches a level corresponding to the signal voltage in a suspension period.

The third section from the top in FIG. 8 indicates a waveform W6 exemplifying change in light quantity of the backlight unit 3 controlled by the backlight unit controller 5. In this exemplary case, light quantity of the backlight unit 3 rapidly decreases at the start of a drive period, then increases moderately, and recovers to an original level during a suspension period subsequent to the drive period. In the display apparatus 1 having luminance that tends to increase upon writing operation, luminance variation is inhibited by decreasing power of the backlight unit 3 at a timing of the writing operation.

The fourth section (at the bottom) in FIG. 8 indicates a waveform W7 of luminance variation in a case where light quantity of the backlight unit 3 is changed as indicated in the third section from the top in FIG. 8. Luminance variation due to signal voltage application during a drive period is moderated in this exemplary case.

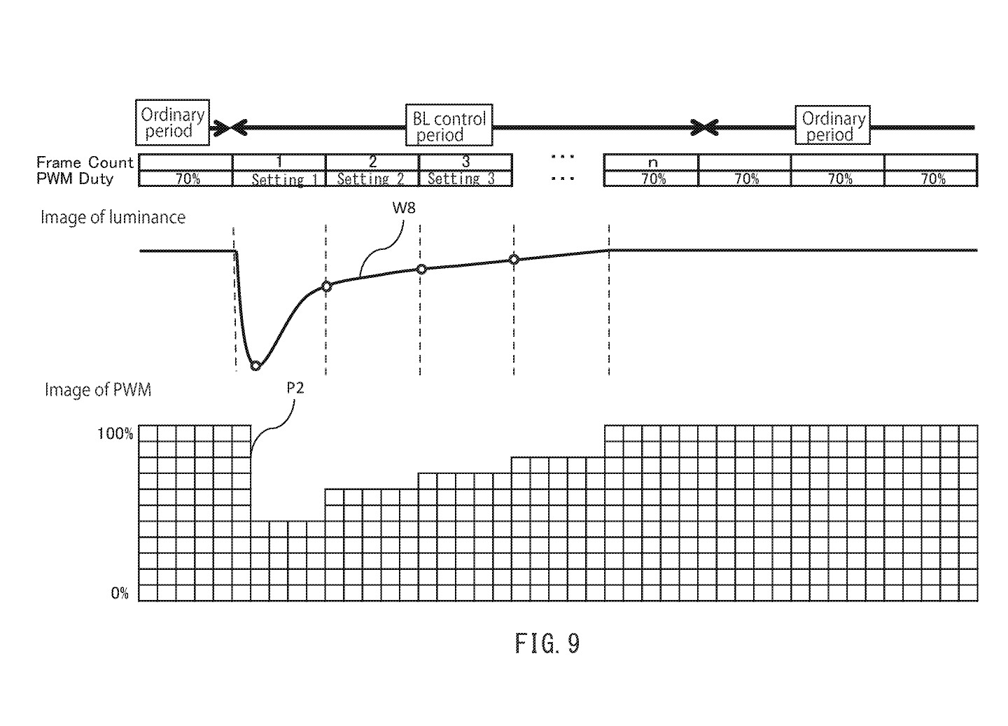

FIG. 9 is an explanatory view exemplifying setting of various values for control of light quantity of the backlight unit in the modification example. FIG. 9 exemplifies setting of a duty ratio during the ordinary period and duty ratios of the n frames during the BL control period, similarly to the exemplary case of FIG. 7. FIG. 9 includes a waveform W8 indicating an image of backlight luminance variation in the modification example, and blocks P2 indicating an image of pulse width in the PWM. In this exemplary case, the duty ratios are set such that light quantity of the backlight unit rapidly decreases and reaches a bottom in the first frame during the BL control period, increases in the second and subsequent frames, and recovers to an original level in the n-th frame. The pulse width in the PWM is set to be the smallest in the first frame, increase stepwise in the second to n-th frames, and be equal to the value for the ordinary period in the n-th frame.

The control of the backlight unit according to the modification example is optionally combined with the control of the backlight unit indicated in FIGS. 5 to 9. For example, operation of increasing light quantity of the backlight unit at a timing of writing operation during a drive period and operation of decreasing light quantity of the backlight unit are optionally switched in accordance with the tone value of each pixel or a different condition. Furthermore, optionally stored is data of a tone value of a current frame associated with set values indicating the amount of change in light quantity of the backlight unit and/or the timing. The backlight unit controller is configured to refer to this data and change light quantity in accordance with a tone value of a drive frame including writing operation.

In a case where every pixel on a single screen in a current frame has a histogram analytical value exceeding a threshold, in other words, in a case where a bright image is displayed in the current frame, the backlight unit can be controlled to decrease light quantity at a timing of writing operation. In another case where every pixel on the single screen in the current frame has a histogram analytical value not exceeding the threshold, in other words, in a case where a dark image is displayed in the current frame, the backlight unit can be controlled to increase light quantity at the timing of writing operation. The histogram analytical value of every pixel is adopted as an index defining brightness of an image displayed in a single frame. The histogram analytical value is calculated from the tone value of each pixel or the like. The index defining brightness of an image is not limited to the histogram analytical value, but any other value obtained from the tone value of each pixel can be adopted as the index.

Optionally stored is data of combination between the tone value of the current frame and a tone value of a previous frame, which is associated with a set value indicating change in light quantity of the backlight unit. For example, preliminarily prepared is data including a set value associated with combination of a value indicating brightness of an image obtained from the tone value of the current frame and a value indicating brightness of an image obtained from the tone value of the previous frame. The backlight unit controller 5 is configured to refer to this data and determine a set value of change in light quantity so as to be associated with combination between the brightness of the image in the current frame and the brightness of the image in the previous frame. Light quantity of the backlight unit can thus be controlled in accordance with luminance variation even in a case where the tone values of the current frame and the previous frame cause a difference in luminance property upon writing operation.

### Second Embodiment

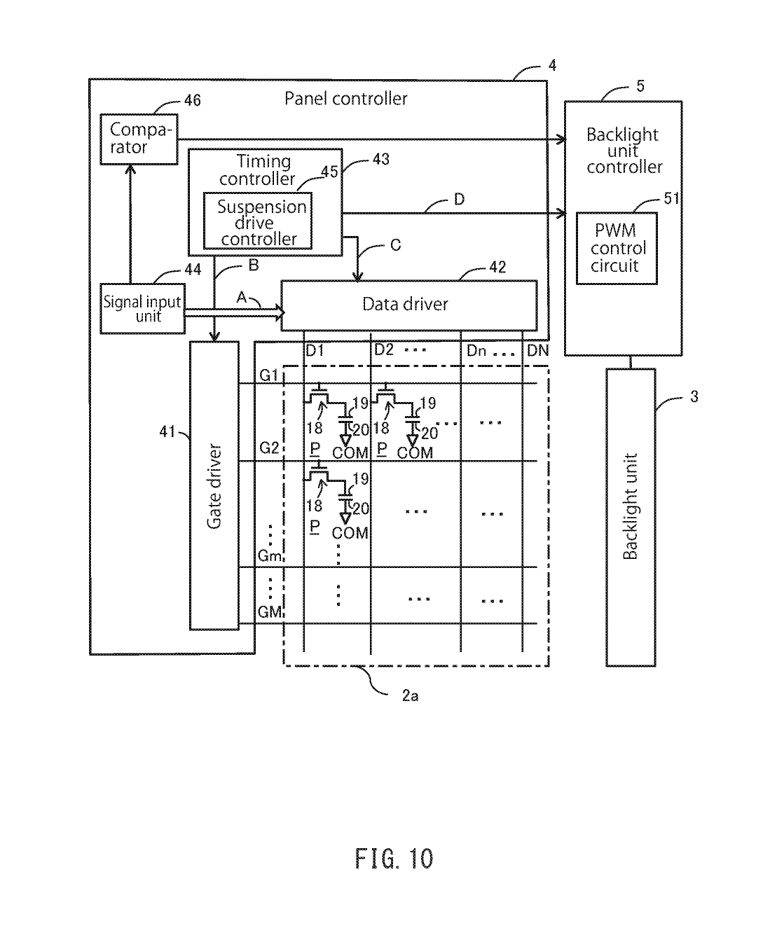

FIG. 10 is a diagram depicting an exemplary configuration of a display apparatus 1 according to the second embodiment. In FIG. 10, portions identical to those of FIG. 3 are denoted by identical reference signs. FIG. 10 exemplarily depicts the panel controller 4 further including a comparator circuit 46 configured to compare an image displayed by writing operation to the display panel 2 and an image displayed by previous writing operation. The backlight unit controller 5 controls whether or not to change light quantity of the backlight unit in synchronization with writing operation in accordance with a result of the comparison by the comparator circuit 46.

The comparator circuit 46 is configured to access a frame memory (not depicted) storing, for each frame, image data supplied from the signal input unit 44, obtain an image in the current frame and an image in the previous frame, and compare these images. The comparator circuit 46 determines whether or not the image in the current frame is changed from the image in the previous frame by determining whether or not the image in the current frame is equal to the image in the previous frame, and supplies the backlight unit controller 5 with a signal indicating whether or not there is change in image. The comparator circuit 46 is thus configured to determine whether or not an image to be displayed by writing operation in a latest drive frame (current drive frame) is equal to an image displayed in a drive frame before the drive frame.

Alternatively, whether or not the image in the current frame is substantially equal to the image in the previous frame is determined in accordance with a checksum (error detection code) obtained by analyzing image data. The frame memory is not always required in this case.

The backlight unit controller 5 receives, from the comparator circuit 46, a signal indicating whether or not there is change from an image in a current drive frame to an image in a previous drive frame. If there is no change from the image in the current drive frame to the image in the previous drive frame, the backlight unit controller is configured to change light quantity of the backlight unit 3 at a timing of writing operation in the current drive frame. Specifically, the backlight unit controller 5 is configured to keep light quantity of the backlight unit 3 unchanged if there is change in image, and change light quantity of the backlight unit 3 if there is change in image. If there is change in image, light quantity of the backlight unit 3 is not changed for saving electric power consumption because luminance variation is unlikely to be visually recognized. In contrast, if luminance variation is likely to be visually recognized with no change in image, light quantity of the backlight unit is changed to efficiently inhibit luminance variation.

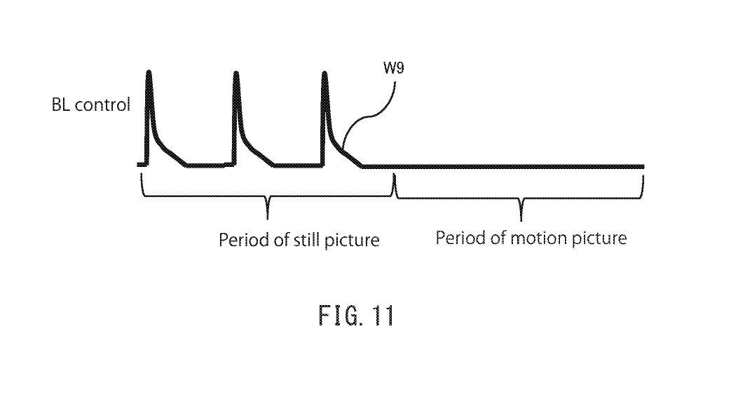

FIG. 11 indicates a waveform W9 exemplifying change in light quantity of the backlight unit 3 controlled by the backlight unit controller 5 according to the present embodiment. In the exemplary case of FIG. 11, the backlight unit controller 5 changes light quantity of the backlight unit 3 at a timing of writing operation while a still picture is displayed with no change in image. Light quantity of the backlight unit 3 is kept unchanged while a motion picture is displayed with change in image in the respective frames. Change in image inevitably causes luminance variation between a previous image and a subsequent image, and there is less significance in inhibiting luminance variation by control of the backlight unit. If there is change in image, operation of controlling the backlight unit is not performed so as to contribute to reduction in electric power consumption.

In the exemplary case of FIG. 11, whether or not to change light quantity of the backlight unit 3 is switchable depending on a case of displaying a still picture or a case of displaying a motion picture. Control of the backlight unit is switched not necessarily depending on whether a still picture or a motion picture is displayed. In a case where images in drive frames before and after a suspension frame are determined to be unchanged regardless of whether a still picture or a motion picture is displayed, the backlight unit controller 5 is configured to change light quantity of the backlight unit at timings of writing operation in the drive frames before and after the suspension frame.

The backlight unit controller 5 is alternatively configured to compare an image by writing operation before a suspension period and an image by writing operation after the suspension period and determine whether or not to change light quantity of the backlight unit in accordance with a result of the comparison. Whether or not light quantity of the backlight unit needs to be changed is thus determined more appropriately in accordance with whether or not there is change in image between before and after the suspension period.

### Third Embodiment

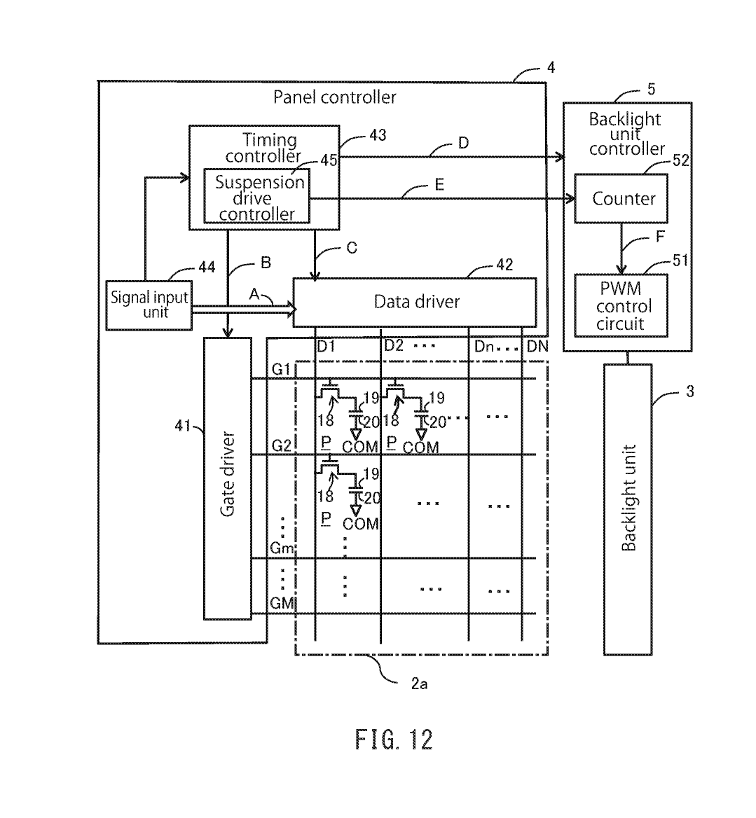

FIG. 12 is a diagram depicting an exemplary configuration of a display apparatus 1 according to the third embodiment. In FIG. 12, portions identical to those of FIG. 3 are denoted by identical reference signs. FIG. 12 exemplarily depicts the backlight unit controller 5 including a counter 52 configured to obtain length of a suspension period in accordance with a signal supplied from the suspension drive controller 45. The backlight unit controller 5 controls whether or not to change light quantity of the backlight unit 3 in accordance with the length of the suspension period.

The suspension drive controller 45 is configured to control a drive period and a suspension period in accordance with an image signal supplied from the signal input unit 44. The suspension drive controller 45 supplies the backlight unit controller 5 with a signal indicating suspension or drive (arrow E). According to an aspect, the suspension drive controller 45 is configured to compare an image in a current frame displayed in accordance with the image signal with an image in a previous frame, and thus determine whether or not to write the image in the current frame. The suspension drive controller 45 distinguishes whether or not each frame is a drive frame or a suspension frame, and transmits a signal indicating a result of the distinction to the counter 52 in the backlight unit controller 5. In an exemplary case, the suspension drive controller 45 is configured to transmit, to the counter 52, a count RESET signal commanding count reset if there is a drive frame.

The counter 52 supplies the PWM control circuit 51 with a signal commanding change in light quantity of the backlight unit 3 if length of a suspension period exceeds a preset value. According to an aspect, the counter 52 is configured to count the number of frames during a suspension period to obtain length of the suspension period. If the number of frames during a suspension period exceeds the set value, the counter 52 transmits, to the PWM control circuit 51, an Enable signal so as to enable change in light quantity of the backlight unit 3. While receiving an Enable signal, the PWM control circuit 51 changes light quantity of the backlight unit 3 at a timing of writing operation in a drive period.

This configuration enables control so as not to change light quantity of the backlight unit with a short suspension period, and control so as to change light quantity of the backlight unit 3 at a timing of writing operation with a long suspension period. Luminance variation due to writing operation is less likely to be visually recognized with a short suspension period, whereas luminance variation due to writing operation is more likely to be visually recognized with a long suspension period. Quality deterioration is inhibited efficiently by controlling the backlight unit to inhibit luminance variation only with a long suspension period and partially skipping operation.

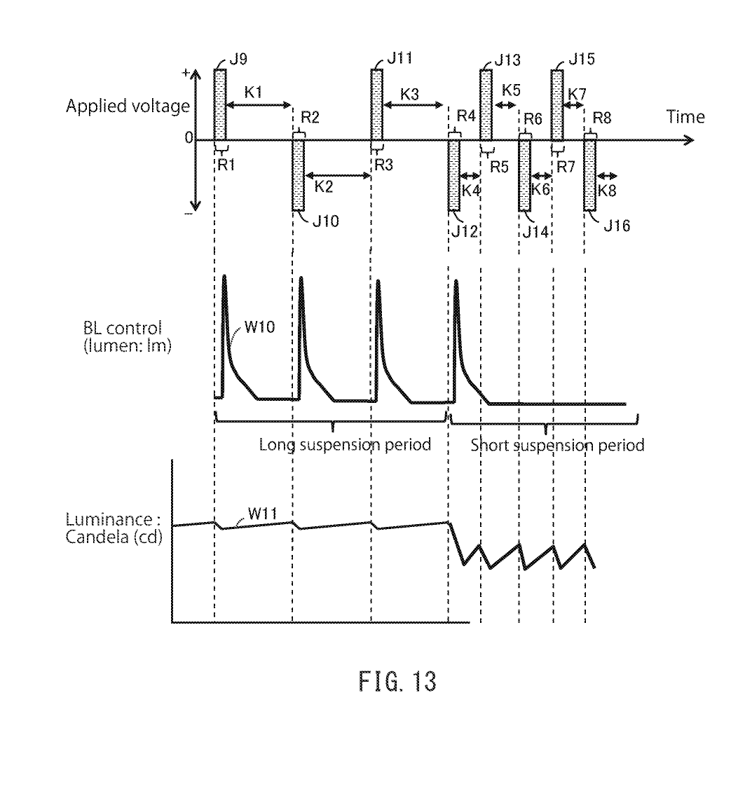

FIG. 13 is a graph indicating exemplary operation of the display apparatus 1 according to the third embodiment. The uppermost section in FIG. 13 indicates temporal change in signal voltage written to the data lines D. FIG. 13 exemplarily indicates a case where drive periods R1 to R8 and suspension periods K1 to K8 are provided alternately. Signal voltages J9 to J16 are applied to the data lines D during the drive periods R1 to R8, respectively. The suspension periods K1 to K3 are longer than the suspension periods K4 to K8. Specifically, the suspension periods K1 to K3 are longer than a preset threshold Th1 (not indicated).

The second section from the top in FIG. 13 indicates a waveform W10 exemplifying change in light quantity of the backlight unit 3 controlled by the backlight unit controller 5. In this exemplary case, the backlight unit controller 5 starts changing light quantity of the backlight unit 3 in the drive periods subsequent to the suspension periods K1, K2, and K3 longer than the threshold Th1, but keeps light quantity of the backlight unit unchanged in the drive periods subsequent to the suspension periods K4, K5, K6, K7, and K8 shorter than the threshold Th1.

The third section (at the bottom) in FIG. 13 indicates a waveform W11 of pixel luminance variation in a case where light quantity of the backlight unit 3 is changed as indicated in the third section from the top in FIG. 13. In this exemplary case, light quantity of the backlight unit 3 is changed to moderate luminance variation due to signal voltage application in the drive periods subsequent to the first to third suspension periods K1 to K3. Light quantity of the backlight unit 3 is kept constant from the fourth drive period RA, but pixel luminance variation is unlikely to be visually recognized because the suspension periods are short. In this case, luminance variation does not influence display quality.

In this exemplary case, visibility of luminance variation due to writing operation is dependent on length of a suspension period and visibility increases with a longer suspension period. Control of the backlight unit is required to counteract luminance variation with a long suspension period, whereas such control is not required with a short suspension period. Circuit operation for control of the backlight unit 3 is not performed with a suspension period shorter than the threshold as indicated in FIG. 13, so as to contribute to reduction in electric power consumption.

The present embodiment can be combined with the second embodiment. According to an aspect, the backlight unit controller 5 is configured to determine whether or not light quantity of the backlight unit 3 needs to be changed in accordance with a result of comparison between an image by previous writing operation and an image by current writing operation and length of a suspension period from the previous writing operation to the current writing operation.

According to the present embodiment, change in light quantity of the backlight unit 3 is controlled in a drive period subsequent to a suspension period of which length is obtained. The backlight unit controller 5 is alternatively configured to determine whether or not light quantity of the backlight unit needs to be changed in a drive period before a suspension period in accordance with an estimated value of length of the suspension period. In a case where image data by writing operation in an upcoming frame is stored in the frame memory and suspension or drive in the upcoming frame is determined in accordance with the stored image data, length of the upcoming suspension period is estimated. In another case where a suspension period is determined in accordance with a preliminarily stored set value or a set value obtained from the outside, length of a suspension period subsequent to writing operation can be estimated from the set value.

### Fourth Embodiment

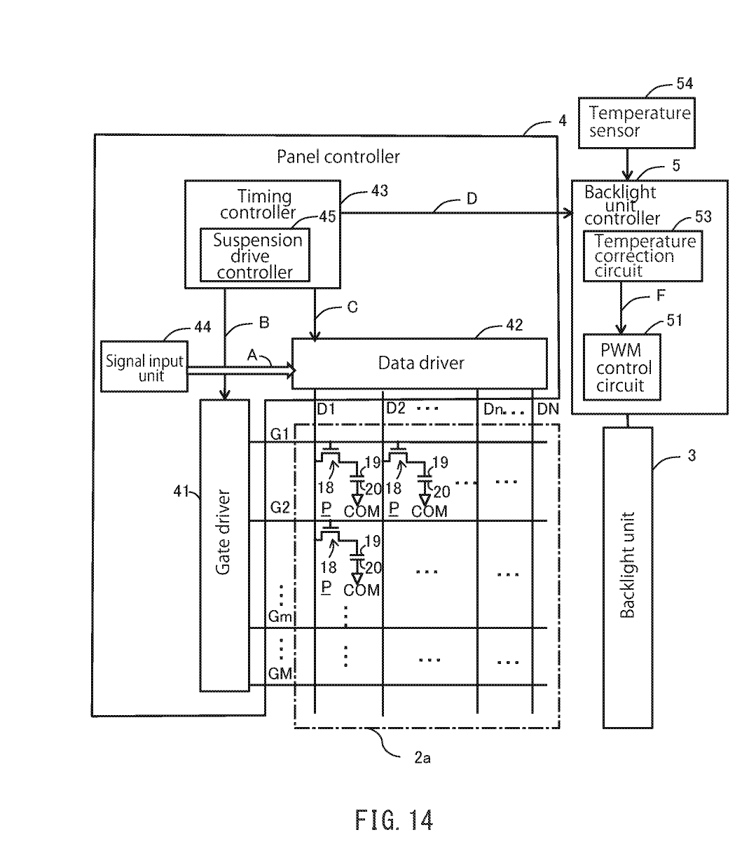

FIG. 14 is a diagram depicting an exemplary configuration of a display apparatus 1 according to the fourth embodiment. In FIG. 14, portions identical to those of FIG. 3 are denoted by identical reference signs. FIG. 14 exemplarily depicts the display apparatus 1 including a temperature sensor 54 configured to detect temperature. The backlight unit controller 5 includes a temperature correction circuit 53 configured to modulate a degree of change in light quantity of the backlight unit 3 in accordance with temperature detected by the temperature sensor 54. The backlight unit controller 5 includes the temperature correction circuit 53 for this purpose.

The temperature sensor 54 detects temperature of the liquid crystal layer of the display panel 2 or a periphery thereof. The temperature correction circuit 53 determines an amount of change in light quantity in accordance with the temperature detected by the temperature sensor 54 and supplies the PWM control circuit 51 with a result of the determination. According to an aspect, data indicating association between temperature and an amount of change in light quantity is stored preliminarily. The temperature correction circuit 53 is configured to refer to the data and determine an amount of change in light quantity associated with the temperature detected by the temperature sensor 54. In an exemplary case, a value indicating an amount of change in light quantity or a timing of the change in light quantity for normal temperature (e.g. at least 10° C. and less than 40° C.), a value for low temperature (e.g. less than 10° C.), and a value for high temperature (at least 40° C.) are stored preliminarily. The temperature correction circuit 53 is configured to read out a value for the temperature detected by the temperature sensor 54 and supply the PWM control circuit 51 with the read value. The PWM control circuit 51 controls light of the backlight unit 3 in accordance with the shared value.

In an exemplary case, the amount of change in light quantity is set to increase as temperature decreases. Liquid crystal tends to have lower response speed as temperature decreases. Accordingly, luminance variation due to writing operation occasionally increases as temperature decreases. In this case, a degree of change in light quantity of the backlight unit is made larger at lower temperature in order to more appropriately inhibit deterioration in display quality.

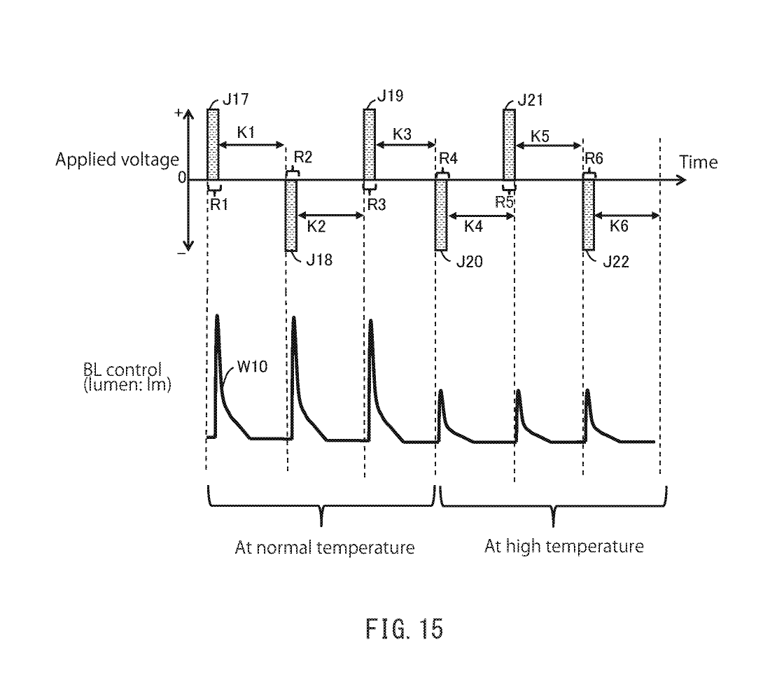

FIG. 15 is a graph indicating exemplary operation of the display apparatus 1 according to the fourth embodiment. The uppermost section in FIG. 15 indicates temporal change in signal voltage written to the data lines D. FIG. 15 exemplarily indicates a case where the drive periods R1 to R6 and the suspension periods K1 to K6 are provided alternately. Signal voltages J17 to J22 are applied to the data lines D during the drive periods R1 to R6, respectively. In this exemplary case, the display panel 2 has temperature within the range of normal temperature (at least 10° C. and less than 40° C.) during the drive periods R1 to R3 and the suspension periods K1 to K3, whereas the display panel 2 has temperature within the range of high temperature (40° C.) during the drive periods R4 to R6 and the suspension periods K4 to K6.

During the drive periods R1 to R3 and the suspension periods K1 to K3 with the temperature detected by the temperature sensor 54 falling within the range of normal temperature, the backlight unit controller 5 sets a first correction amount for normal temperature to an amount of change in light quantity of the backlight unit 3. During the drive periods R4 to R6 and the suspension periods K4 to K6 with the detected temperature falling within the range of high temperature, the backlight unit controller 5 changes light quantity by a second correction amount less than the first correction amount. Liquid crystal has higher response speed at higher temperature, and a luminance correction amount by control of the backlight unit can thus be made smaller. In contrast, the luminance correction amount by control of the backlight unit can be made larger at lower temperature. Luminance amendment by control of the backlight unit is achieved more appropriately in accordance with a temperature property of the driven display panel 2. Combining the temperature sensor and the temperature correction circuit in this manner achieves improvement in display quality.

The fourth embodiment is applicable to any one of the first to third embodiments and any one of embodiments achieved by combining at least two of the first to third embodiments.

The embodiments of the present invention have been described above, although the present invention should not be limited to the first to fourth embodiments. For example, the first to fourth embodiments exemplify the case of driving all the gate lines G in the display and suspension driving by stopping signal input to all the data lines D for a predetermined number of frame periods. Suspension drive is performed alternatively by stopping part or all of the gate lines G in the display for the predetermined number of frame periods, or by stopping data signal supply to the data lines D for the predetermined number of frame periods. Still alternatively, supply of control signals such as clock signals to drive circuits to be stopped (the data driver 42 and the gate driver 41) is stopped during suspension drive.

The manners of mounting the panel controller 4 and the backlight unit controller 5 are not limited to the exemplary cases described above. Alternatively, the panel controller 4 and the backlight unit controller 5 are configured by a single semiconductor chip or circuit. Still alternatively, the panel controller 4 and the backlight unit controller 5 are mounted at least partially by means of the circuits on the active matrix substrate. In the configuration depicted in FIG. 14, the temperature correction circuit 53 is alternatively provided not in the backlight unit controller 5 but in the panel controller 4.

The display apparatus according to the present invention is not limited to a liquid crystal display apparatus. The present invention is also applicable to any display apparatus possibly having similar problems, such as a particle migration display apparatus configured to cause particle migration due to voltage application so as to perform display control.

1. A display apparatus comprising:
a display panel including a display provided with a plurality of pixels;
a backlight unit configured to emit light to the display;
a panel controller configured to control writing operation of supplying each of the pixels with a signal to display an image in the display, and a suspension period provided between the writing operation and writing operation performed before or after the writing operation; and
a backlight unit controller configured to control a light quantity of the backlight unit in synchronization with the writing operation.

2. The display apparatus according to claim 1, wherein the backlight unit controller determines whether or not to change the light quantity of the backlight unit in synchronization with the writing operation in accordance with a result of comparison between the image displayed by the writing operation and an image displayed by writing operation performed before the writing operation.

3. The display apparatus according to claim 1, wherein the backlight unit controller determines whether or not to change the light quantity of the backlight unit in synchronization with the writing operation in accordance with length of the suspension period.

4. The display apparatus according to claim 1, wherein the backlight unit controller controls to change the light quantity at a plurality of steps in a certain period.

5. The display apparatus according to claim 1, further comprising:
a temperature sensor configured to detect temperature; wherein
the backlight unit controller modulates a degree of change in light quantity of the backlight unit in accordance with the temperature detected by the temperature detector.

6. The display apparatus according to claim 1, wherein the panel controller sequentially selects lines of the pixels disposed in a matrix form in the display by supplying scanning lines connected to the lines with scanning signals and supplies the pixels on the selected lines with data signals to display the image in the writing operation, and stops writing data signals partially or entirely in the display during the suspension period.

7. The display apparatus according to claim 1, wherein
the display panel includes an active matrix substrate,
the active matrix substrate includes
scanning lines and data lines disposed to cross the scanning lines,
a pixel electrode provided at each of the pixels defined by the scanning lines and the data lines, and
a thin film transistor,
the thin film transistor has a semiconductor layer containing an oxide semiconductor disposed to face an electrode connected to a corresponding one of the scanning lines, a first electrode connected to the pixel electrode, and a second electrode connected to a corresponding one of the data lines, and
the first electrode and the second electrode are provided apart from each other on the semiconductor layer.

8. The display apparatus according to claim 7, wherein the oxide semiconductor is InGaZnOx mainly containing indium (In), gallium (Ga), zinc (Zn), and oxygen (O).

9. The display apparatus according to claim 1, wherein the display panel includes an active matrix substrate and a counter substrate provided to face the active matrix substrate with a liquid crystal layer being interposed therebetween.

10. A control device of a display apparatus including a display panel having a display provided with a plurality of pixels, and a backlight unit configured to emit light to the display, the control device comprising:
a panel controller configured to control writing operation of supplying each of the pixels with a signal to display an image in the display, and a suspension period provided between the writing operation and writing operation performed before or after the writing operation; and
a backlight unit controller configured to control light quantity of the backlight unit in synchronization with the writing operation.
